(19) United States
(12) Patent Application Publication
(10) Pub. No.: US 2005/0093556 A1
(43) Pub. Date: May 5, 2005

(54) Method and apparatus for determining characteristics of a sample liquid including a plurality of substances

(76) Inventors: Rudolf Mueller, Starnberg (DE); Dietrich Wabner, Garching (DE); Hanns-Erik Endres, Muenchen (DE); Ilse Wurdack, Muenchen (DE); Peter Pfeiffer, Muenchen (DE)

Correspondence Address: GLENN PATENT GROUP, 3475 EDISON WAY, SUITE L, MENLO PARK, CA, 94025, US

(21) Appl. No.: 09/786,294

(22) Filed: Feb. 23, 2001

(30) Foreign Application Priority Data
Feb. 24, 2000 (EP) 00103882.7

(51) Int. Cl. G01R 27/08

(52) U.S. Cl. 324/693

(57) ABSTRACT

The method according to the invention for determining characteristics of a sample liquid including a plurality of substances includes the recording current-voltage measurement data of a liquid with at least one known characteristic, the transforming of measurement data of the liquid into a feature space to obtain a first plurality of feature values, the recording of current-voltage measurement data of the sample liquid, the transforming of measurement data of the sample liquid into the feature space to obtain a second plurality of feature values, and the determining of at least one characteristic of the sample liquid based on the feature values of the sample liquid in relation to the feature values of the liquid with the at least one known characteristic.

The present invention relates to the examination of liquids, especially of body liquids, such as urine, liquor, etc., or of liquid foods. More particularly, the present invention relates to the field of urine diagnosis.

Urine examinations are known in the prior art. Since they are non-invasive, they do not stress the patients and every increase in information from such examinations is of special commercial interest. At present, two methods of examining a urine liquid are substantiallv available. In the first method, test strips which are coated with up to 20 chemicals and which change their colors upon coming into contact with special substances are used. These test strips are dipped into the urine sample to be examined. Thus, without great expenditure, a judgment, which, however, substantially only is a qualitative one, because a certain threshold value of the substance to be determined must be present in order to trigger a change in color, can be achieved. In the second method, an infra-red spectrum of a urine sample, to which certain reagents may have been added before, is recorded and evaluated. However, devices which are capable of carrying out these infra-red spectrum analysis, require a considerable investment of about DM 200.000,00. For this reason they are mainly uses in hospitals. Both the technical requirements of the devices and the logistic requirements in order to bring several urine samples into a laboratory for a spectrum analysis to carry out the examinations and to associate results to the respective urine samples and to send the results to the respective physicians, require considerable expenditure, such as in the bookkeeping department, in transportation, etc. Although such an infra-red spectral examination usually only takes 20 minutes, several hours go by in the case of a laboratory within the hospital and several days go by in the case of residnet physician, until the physician is in possession of the results.

For examining liquids of all kinds, measuring instruments for recording cyclovoltagrams, are known in the prior art. Such measuring instruments are, by cyclically applying a voltage ramp to a sample liquid and by simultaneously measuring the resulting electrode current, capable of recording a current-voltage characteristi characteristic of the sample liquid which, in turn, yields information about respective electrode processes of the ingredients of the sample liquid. This kind of examination is therefore also called “electro-chemical spectroscopy”. The electrode processes, which contribute to the current-voltage characteristic, include reduction processes, oxidation processes, preceding or succeeding chemical reactions, adsorptions of reactants or products, electrode depositions, etc. The said contribute additively to the current-voltage characteristic, the so-called cyclovoltagram. Thus, cyclovoltagrams provide a quick overview for the behavior of an electro-chemical system.

However, at present, evaluating the voltametrically-obtained measuring graphs require the specialist who is able to recognize typical graph forms from the graph forms and who draws a conclusion from the reactions present and the substances present in the substrate. Such evaluation of data by the practical man, the physician or the laboratory personnel, respectively, is almost impossible in most of the cases, because the effects of the different electrode processes on the cyclovoltagram superimpose one another.

It is the object of the present invention to provide an easier method and an easier apparatus for determining the characteristics of a sample liquid including a plurality of substances, which enable a quick determining of characteristics of a sample liquid

This object is achieved by a method of claim 1 and an apparatus of claim 16.

The inventive method for determining characteristics of a sample liquid including a plurality ot substances includes recording current-voltage measurement data of a liquid with at least one known characteristic, transforming the measurement data of the liquid into a feature space in order to obtain a first plurality of feature values, recording current-voltage measurement data of the sample-liquid, transforming the measurement data of the sample liquid into the feature space in order to obtain a second plurality of feature values and determining at least one characteristic of the sample liquid based on the feature values of the sample liquid in relation to the feature values of the liquid with the at least one known characteristic.

The inventive apparatus for determining characteristics of a sample liquid including a plurality of substances includes a first recording means for recording current-voltage measurement data of a liquid with at least one known characteristic and current-voltage measurement data of the sample liquid, a first processing means for transforming the measurement data of the liquid into a feature space to obtain a first plurality of feature values and for transforming the measurement data of the sample liquid into the feature space to obtain a second plurality of feature values, and a second processing means for determining at least one characteristic of a sample liquid based on the feature values of the sample liquid in relation to the feature values of the liquid with the at least one known characteristic.

According to one embodiment, a plurality of current-voltage measurement data of a plurality of reference liquids are recorded for determining the at least one characteristic of a sample liquid. Here, these current-voltage measurement data correspond to cyclovoltagrams which are obtained by cyclically applying a voltage ramp in both directions and simultaneously measuring the electrolysis current. The resulting measurement data are then subjected to a mathematical operation, such as a Fourier transformation, a wavelet transformation or the like. A power spectrum is cut out of the resulting “spectral” or transformed measurement data to reduce the amount of data for the subsequent processing. From these spectral measurement data, of which the amount has been reduced, (and which from now on is simply referred to as “reduced”) of the plurality of reference liquids, a transformation matrix, which maps the measurement data into a low dimensional feature space, is determined by means of a main component analysis. Current-voltage measurement data of a plurality of liquids with at least one known characteristic are then recorded, subjected to a spectral transformation and mapped into the feature space by means of the transformation matrix, wherein a first plurality of feature values forms. The same steps are carried out to obtain feature values of the sample liquid with an unknown composition of substances. on comparing the feature values of the liquid with at least one known characteristic and the sample liquid with the unknown composition of substances, the sample liquid can then be associated with a certain class, such as “urine sample of a patient who has not been given vitamin C before taking the sample”, or a certain physical value of the urine sample, such as the concentration of a certain ingredient, can be detected quantitatively.

Consequently, the present invention closes the gap between the two methods mentioned before, the test strips and the infra-red spectral analysis In contrast to the usage of test strips, the present invention is capable of providing quantitative results. Further, this is possible with considerably less expenditure than is the case with infra-red spectral analyses. The estimated cost for the apparatus for realizing the present invention is, for example, DM 20.000,00 in the beginning and approximately DM 5.000,00 when a larger number of them is produced, and is, thus, considerably lower than the purchase costs of DM 200.000,00 for an infra-red spectral analysis device, The measurement and the judgment of the samples can be carried out locally, such as at a resident physicians and immediately, whereby the typical duration of the measurement is approximately one to two minutes. Consequently, the risk of an uncontrolled change of the sample, such as a segregation of the sample, slow chemical reactions and influence by the action of light and temperature fluctuations resulting from a non-defined transport or storing is also avoided.

Since the present invention fundamentally differs from the methods mentioned above, results which can be used as a supplement to the conventional methods can be further obtained.

The application of the present invention is further not limited to the examination of urine, but it can be used with liquids of all kinds, such as other body liquids, liquid foods, washing liquids (washing liquor), etc.

Preferred embodiments of the present invention are described hereinafter making reference to the appended drawings, in which:

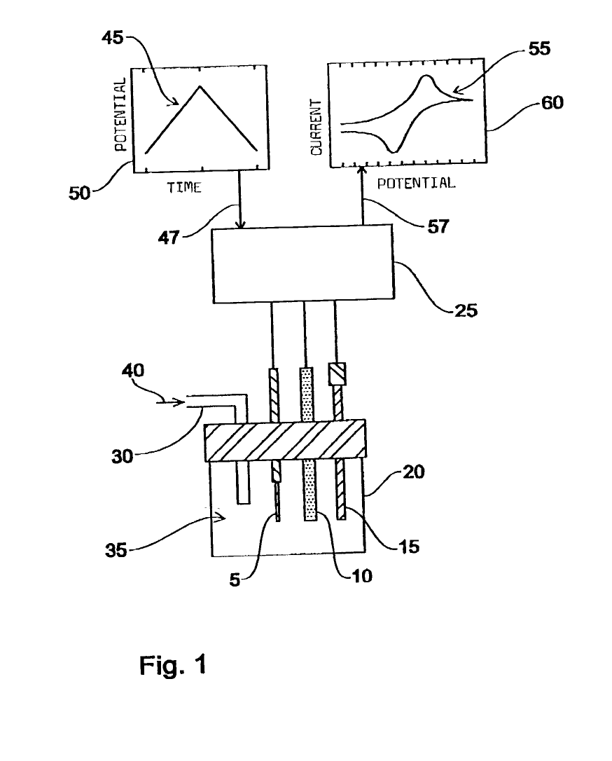

FIG. 1 is a schematic view of the structure of a measuring means for recording cyclovoltagrams, as it can be used in the present invention;

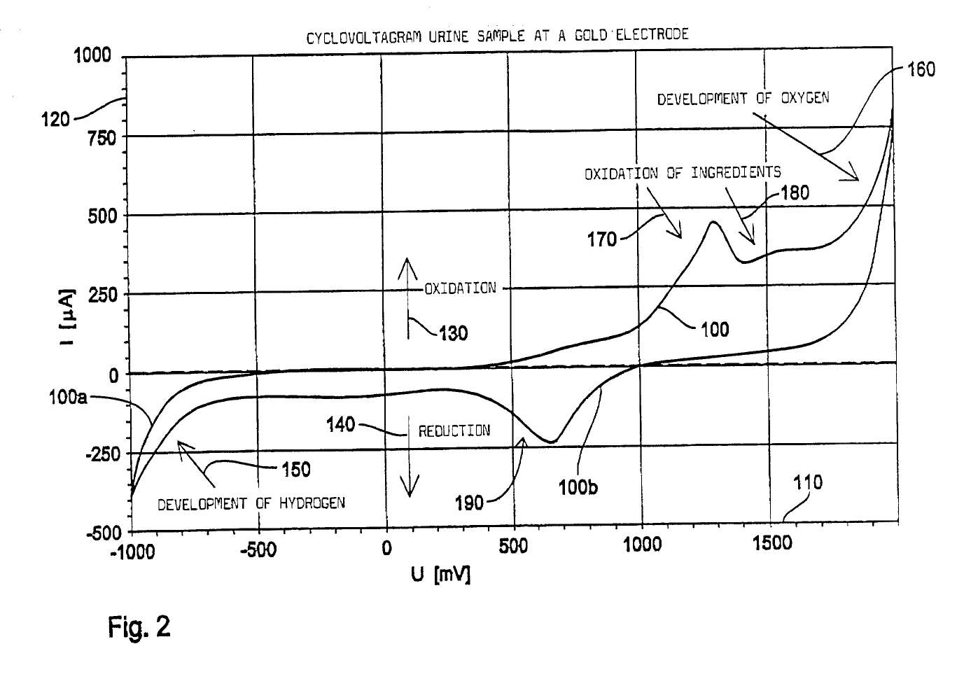

FIG. 2 is a cyclovoltagram as it is obtained from measuring a urine sample by means of a gold electrode;

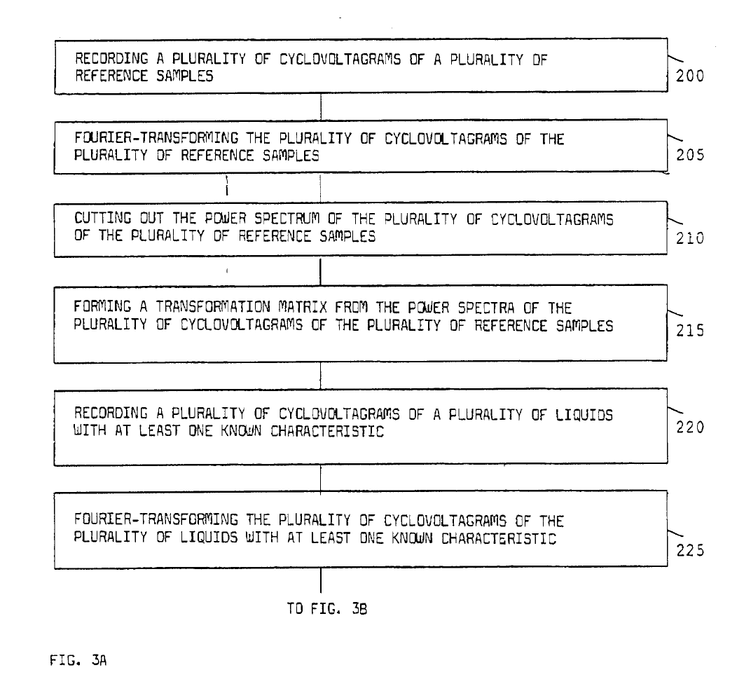

FIG. 3a is the first part of a flow chart which describes the steps of an embodiment of the inventive method;

FIG. 3b is the second part of the flow chart of FIG. 3a;

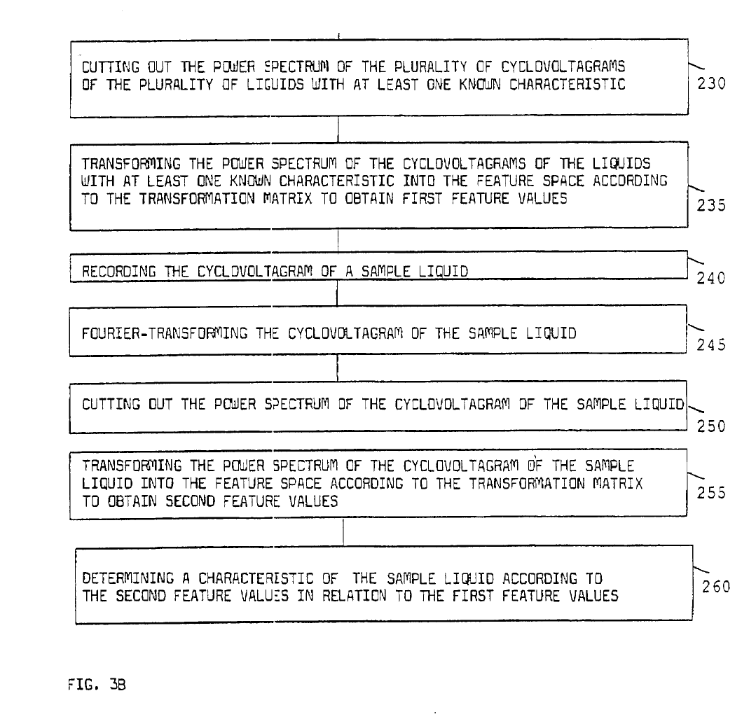

FIG. 4 illustrates several cyclovoltagrams of samples which have been taken at different points in time before and after administering vitamin C or the addition of vitamin C;

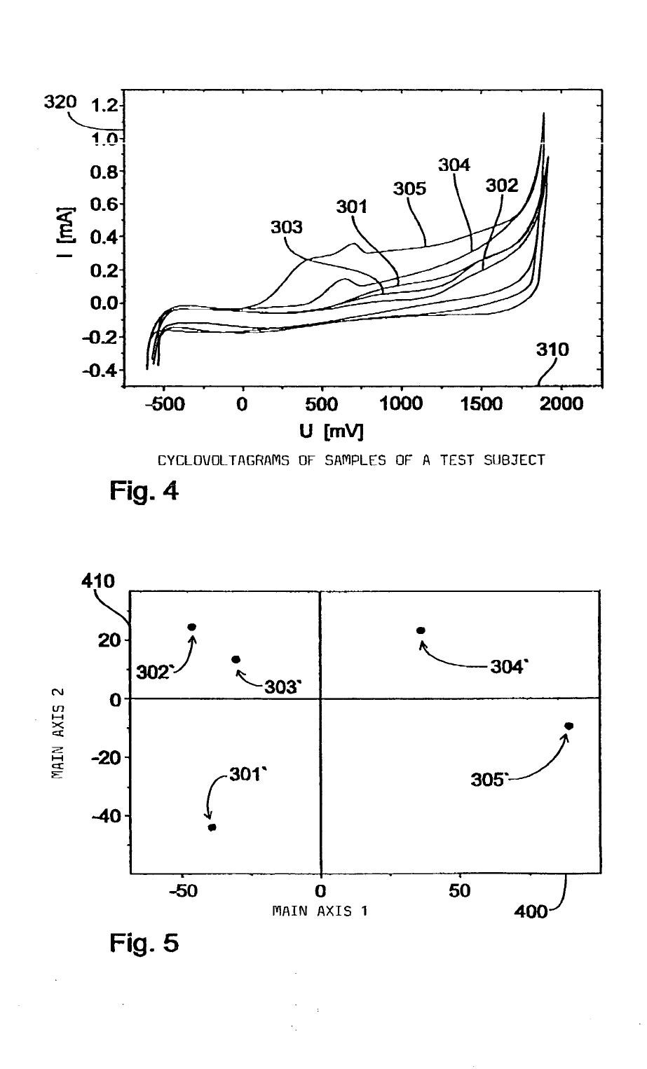

FIG. 5 is a feature space which is spanned by eigenvectors obtained by a main component analysis, and which includes feature values which correspond to the cyclovoltagrams of FIG. 3; and

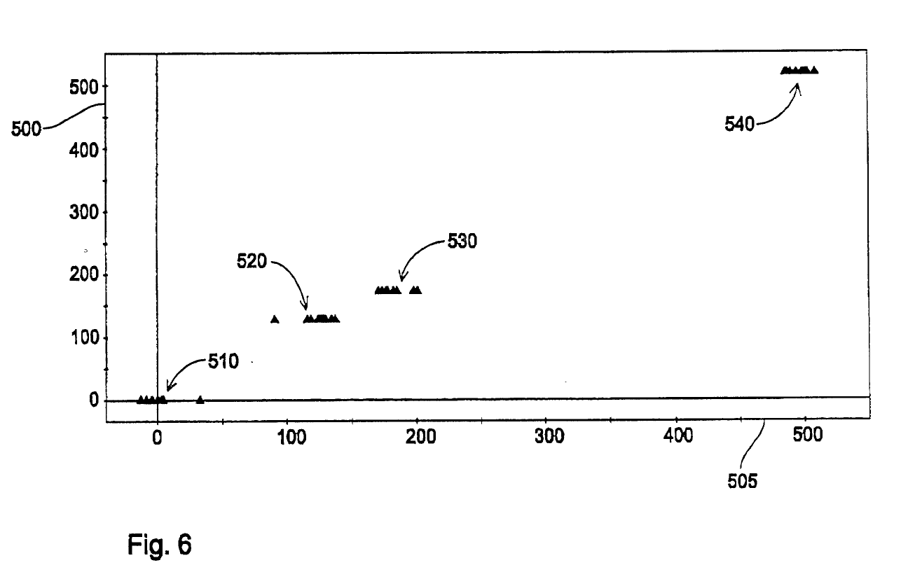

FIG. 6 illustrates a plot of time values which have been determined at different points in time for four urine liquids according to the invention taken and which indicate the length of time between the taking and the administration of vitamin C, versus the actual lengths of time.

At first, reference is made to FIG. 1 which shows an apparatus for recording current-voltage measurement data. In the illustrated embodiments, the apparatus is an apparatus for generating a cyclovoltagram of a sample liquid. This recording means or measuring means for recording cyclovoltagrams substantially consists of three electrodes, namely a counter electrode 5, a working electrode 10 and a reference electrode 15, a measurement chamber 20 in which the three electrodes 5, 10 and 15 are located and a potentiostat 25 which comprises a voltage source and a current measuring device (not shown) and which is connected with the three electrodes 4, 10 and 15. It further comprises a gasification means 30, such as a tube, through which an inert gas, such as nitrogen or argon, can be introduced into a liquid 35, such as a sample liquid or calibrating liquid, contained in the measurement chamber 20, as it is shown by an arrow 40, to optionally drive out oxygen contained in the liquid 35. It also comprises an appropriate apparatus, which is not shown due to clarity reasons, such as a tube ending at the bottom of the measurement chamber, for introducing the liquid 35 into the measurement chamber 20.

The operation of the measuring means is now explained. Via the potentiostat 25, a variable voltage which can be input into the potentiostat 25, as is indicated by the arrow 47, is applied between the counter electrode 5 and the working electrode 10. For this purpose, by means of the reference electrode without current 15, which is preferably located in the vicinity of the working electrode 10, a defined reference potential is predetermined for the working electrode 10. The course or waveform of potential 45, that is the potential change as a function of the time, is predetermined by the potentiostat 25 between the working electrode 10 and the reference electrode without current 15. The course of potential 45 is illustrated in an examlary plot 50, showing the potential versus the time. As it can be seen, the course of potential 45 corresponds to a cyclic repetition of a saw-tooth shaped wave form or the cyclic passing of a potential ramp in both directions, that is from a negative to a positive potential and vice-versa respectively. The potentiostat 25 also measures the current flowing between the counter electrode 5 and the working electrode 10. The potentiostat 25 outputs the measured current wave form as current-voltage measurement data and as a cyclovoltagram 55 (arrow 57) respectively, as it is exemplarily shown in 60, where the current is shown versus the potential (voltage).

It is noted that, although it is not shown in FIG. 1, the counter electrode 5 preferably is large compared to the working electrode 10, so that it is only the electrochemical processes on the working electrode 5 that have a limiting effect on the measured flow of current. The active area of the counter electrode is, for example, fifty times larger than, but at least twice as large as the working electrode.

Although it was described above that the sample liquid 35 is introduced into the measurment chamber 20, it is also possible to dip the three electrodes 5, 10 and 15 into the sample liquid 35. Further, in the last-mentioned implementation, it is also possible to implement the electrodes as a probe which can be used as a disposable probe via an appropriate quick change apparatus. In order to transmit the signals from the electrodes to the potentiostat, such a probe can also comprise an integrated preamplifier to amplify the current,

It is also noted that an apparatus which avoids temperature fluctuations or which adjusts a defined temperature at the electrodes, i.e. a thermostatic functioning, may be provided since the reactions taking place at the electrodes can also be dependent on the temperature.

It is also noted that different materials, such as platinum, gold or graphite, are possible for the electrode material. It is only substantial that the electrode material is inert with respect to the chemical processes occurring in order to achieve an adequate stability.

Reference is now made to FIG. 2 which shows a cyclovoltagram which has been recorded by the measuring means of FIG. 1. In this case, a urine sample has been used as a sample liquid and gold has been used as the electrode material. FIG. 2 shows a cyclovoltagram wherein the x-axis shows the voltage applied or the potential U measured in mV respectively and the y-axis 120 shows the measured current I measured in pA. As it is illustrated by the arrows 130 and 140, negative currents correspond to reduction processes, while positive currents correspond to oxidation processes. Since a urine sample contains water as the main ingredient, the potential area for the cyclovoltagram, that is the potential window, is determined by the development of hydrogen with low potentials and by the development of oxygen with high potentials. In the Figure, the potential area of a beginning development of hydrogen in the cyclovoltagram 100 is illustrated by an arrow 150 and the potential area of a beginning development of oxygen is illustrated by an arrow 160. In the present aqueous system, that is the urine sample, these potentials are located at about −1000 mV and +1100 mV respectively.

Within these potential windows, oxidizable or reducible ingredients of the water in the urine sample respectively can be converted electrochemically at certain potentials. These processes cause current flows which are measured by the potentiostat 25 (FIG. 1) and which can be seen in the cyclovoltagram 100 as peak 170 and 180 respectively. Since different ingredients of the sample liquid are oxidized and reduced at different potentials, a statement about the kind of the ingredient can be made by the position of the current peaks, that is at which potential the current peak occurs. Further, the height of the peaks 170 and 180 at which the current peak occurs, that is the current present at the potential, provides information about the concentration of the substance.

As it can be seen, the cyclovoltagram 100 comprises two current values for each potential value, so that the cyclovoltagram 100 is composed of an upper branch 100a and a lower branch 100b, respectively. Here, the upper branch 100a corresponds to the current value measured during the linear potential increase and the lower branch 100b corresponds to the current values measured during the linear potential decrease. If, during the potential increase, the potential approaches the oxidation potential of a certain ingredient, the current measured increases. As a consequence, the surface concentration of the reacting ingredient at the respective electrode, that is the working electrode, decreases with a further increase in the potential, and at the same time a growth of the diffusion layer starts. After reaching a maximum reaction current, such as at 170, the concentration gradient and thus the speed of the electrochemical reaction and the current respectively decrease again, whereby a respective oxidation peak forms (as at 170 and 180, wherein these peaks are superimposed by the development of oxygen 160). When passing these potentials in the opposite direction, if the respective process is reversible, the oxidation process is reversed, that is, a reduction takes place. The current and potential values of the resulting oxidation and reduction peaks, for example, 170 respectively, supply information about the reversibility (peak current difference) and the reduction potential (potential difference) of the respective ingredients. In the present sample liquid (urine), the respective electrode reactions of the ingredients seem to be irreversible. It is noted that the precise features of the peaks, that is, peak current value, peak width, etc., are dependent on the scan speed, that is, the gradient of the potential ramp. Further, the peak which can be observed at 190 is mainly the result of a covering layer phenomenon and depends on the electrode material used. In the present case of gold as the electrode material, peak 190 is caused by a gold oxide reduction

As it can be observed, however, urine is a very complex medium with a large number of different ingredients, so that in the cyclovoltagram 100 of a urine sample, a large number of peaks 170 and 180 superimpose one another. The reason for this is that on the one hand, several of these ingredients are oxidized or reduced at potentials which are positioned very close to one another and that, on the other hand, only the total current flow caused is measured.

As to the chemophysical processes in the cyclovoltrametry and the connections between physical quantities and the course of the cyclovoltagram, reference is made to the book “Elektrochemie” by C. H. Hamann and W. Vielstich, Weinheim, 1998, which is published by the Wiley-VCH Verlag, and to the article “Cyclovoltammetrie—die Spectroskopie des Elektrochemikers” by J. Heinze in Angewandte Chemie, Vol. 96, 1984, pages 823 to 916, which are incorporated here by reference.

Referring to FIG. 3, an embodiment of an inventive method for determining characteristics of a sample liquid including a plurality of substances is now described. In a step 200, a plurality of cyclovoltagrams of a plurality of liquids which are suitable for being used as reference liquids, are recorded. In the case of an examination of urine, these reference liquids are urine samples of normal test subjects, that is of persons who, as far as their health is concerned, are thought to be normal. The test subjects can also be persons who have not been given additional substances before taking the urine samples. Those voltagrams are then present in the form of measuring vectors. Referring to these measuring vectors, a mathematical operator, such as a Fourier transformation, a wavelet transformation, etc., is applied in a step 205. The spectral measuring vectors obtained comprise as many entries as the measuring vectors which have been recorded in step 200. In order to reduce the amount of data to be processed thereafter, a power spectrum is, in a step 210, preferably cut out of the spectral measuring vectors, that is a field of subsequent entries of the spectral measuring vectors, the sum of which is larger than a certain percentage of the total sum of all entries of the spectral measuring vectors is removed.

These “reduced” spectral measuring vectors are subjected to a main component analysis in a step 215, as it is known to the prior art and is, for example, described in the book “Statistiche Datenanalyse” by Werner A. Stahel, pages 307 following, which was published by the Vieweg-Verlag. By means of the main component analysis, a transformation matrix is determined which transforms the reduced spectral measuring vectors into a low dimensional co-ordinate system or a feature space respectively. For this purpose, a covariance matrix and the eiqenvectors and eiqenvalues belonging thereto are determined from the reduced spectral measuring vectors. The number and the size of the eigenvalues are a measure for the number of features that can be extracted from the measuring values which have been determined in step 200, because many of the measuring values can be redundant and can thus, if at all, only contribute marginally to the eigenvector system. The transformation matrix is determined in such a way that it corresponds to a mapping rule of reduced spectral measuring vectors into the feature space and that the feature space is spanned by those eigenvectors whose eigenvalues exceed a threshold value which has been empirically predetermined. Thus, the step 215 ensures that this mapping rule is adjusted to the sample liquids, for example urine, to be measured. The threshold value can be adjusted to enable an adequately high statistical security referring to the following evaluation of the sample liquids.

After the mapping rule has been determined in step 215, to map the reduced spectral measuring vectors into the feature space, steps 200, 205 and 210 are repeated in steps 220, 225 and 230 with respect to a liquid of which at least one characteristic is known. This characteristic can, for example, include the concentration of a certain ingredient of the liquid or simply be a qualitative statement about the liquid, such as the statement that it has passed a certain expiry date or that it has been treated in a certain way, for example, by the addition of vitamin C. In a step 235, by means of the transformation matrix determined in the step 215, a first feature point is determined in the feature space from a recorded cyclovoltagram of the liquid with the at least one known characteristic. Steps 220, 225, 230 and 235 can also be carried out for several liquids, wherein several feature points form.

In steps 240, 245, 250 and 255, the steps 220, 225, 230 and 235 are repeated for the sample liquid to be examined, of which no characteristic is known, whereby a second feature point forms.

The feature point obtained in step 255 and the feature points obtained in step 255 respectively (one feature point for each dimension of the feature space) are then, in a step 260, either associated qualitatively to a certain class which corresponds to a certain characteristic or associated quantitatively to a certain value, as it is explained in greater detail referring to FIGS. 4, 5 and 6. This association is carried out by comparing the second feature values with the first feature values which have been extracted from cyclovoltagrams of samples which comprise at least one known characteristic On the basis of feature values of body liquids of test subjects with a known state of illness, a class association can, for example, mean determining an illness of the test subject of whom the respective sample liquid, such as urine, liquor, etc., has been taken. On the basis of feature values of samples with a known composition of substances the determination of a quantitative value can, for example, be the determination of the concentration of an ingredient or the like.

It is noted that it is possible to use the same cyclovoltagrams in steps 205 and 220. It is also possible to omit steps 205, 210, 225, 230, 245 and 250 and to apply steps 215, 235 and 255 directly on the cyclovoltagrams instead. For clarity, it is also noted that the characteristic determined in step 250 is always related to an attribute, such as a concentration, a state of illness, etc., which the at least one known characteristic of the liquid of step 220 relates to.

Since the covering layer phenomena (confer 190 in FIG. 2) are dependent on the electrode material used (the peak at 190 is, as mentinned above, an effect of the covering layer phenomenon and no reduction peak corresponding to the oxidation peak 170) and thus each course of cyclovoltagram depends on the electrode material used, it can be advantageous to use the same electrode material when recording the cyclovoltagrams in the steps 200, 220 and 240. It is also possible to carry out steps 200, 220 and 240 several times, so that for each liquid cyclovoltagrams are obtained using different electrode materials, that is, for example, that each cyclovoltagram measurement is carried out with gold, platinum and graphite as the electrode material. The resulting cyclovoltagrams for a liquid may then be combined for the following processing to form one measuring vector. The advantage is that the covering layer phenomena provide additional information about the respective liquids, wherein this information can lead to improved results in the method of FIG. 3.

A further adjusting parameter which can be considered when recording the cyclovoltagrams is the scan speed. Since the scan speed influences the precise form of the oxidation and reduction peaks, the course of the cyclovoltagram depends on the scan speed used for recording. For this reason, it can be advantageous to chose the same scan speed for the steps 200, 220 and 240. It can, in turn, be advantageous to carry out each cyclovoltagram recording using different scan speeds and to combine the resulting cyclovoltagrams to form one measuring vector. Thereby, further information about the liquids may be obtained from the diffusion processes and penetrating reactions at the electrodes and can be used for the succeeding evaluation.

It is also noted that, especially in the case of body liquids, it can be advantageous to adjust the different liquids before carrying out the steps 200, 220 and 240, to the same conductivity value by diluting. Otherwise, it can occur in the case of urine samples that the urine samples of patients have different concentrations, depending on the amount of liquid the patient has taken in prior to taking the sample. Since the peak current height depends on the concentration of the ingredients, the course of the cyclovoltagram depends on the concentration. By adjusting all the liquids to the same conductivity value prior to according a cyclovoltagram, the cyclovoltagrams obtained can be standardized.

Reference is now made to FIG. 4 which illustrates five cyclovoltagrams 301, 302, 303, 304 and 305 which have been measured by the measuring means of FIG. 1 with respect to urine samples which have been taken from a test subject at different points in time after administering vitamin C or before administering vitamin C or which have been obtained from a urine sample which has been taken from the test subject before administering vitamin C and to which vitamin C has been added after the taking. The following applies to the cyclovoltagrams 301 to 305 that:

TABLE 1

| Cyclovoltagram | Taking |
|---|---|
| 301 | Taking of urine sample prior to |
| | administering vitamin C |
| 302 | Taking of urine sample 2 hours after |
| | administering vitamin C |
| 303 | Taking of urine sample 3 hours after |
| | administering vitamin C |
| 304 | Taking of urine sample 5 hours after |
| | administering vitamin C |
| 305 | Taking of urine sample prior to |
| | administering vitamin C with subsequent |
| | addition of vitamin C |

The cyclovoltagrams 301 to 305 are illustrated, wherein the x-axis 310 shows the applied voltage in mV and the y-axis 320 shows the measured current in mA along the Y-axis 320.

The cyclovoltagrams 301 to 305 show differences in the courses of the cyclovoltagrams which, by the present invention, can be evaluated more precisely and in a more stable way, wherein it is possible according to the invention to recognize signal differences which are not accessible to a visual evaluation.

The cyclovoltagrams 301 to 305 have been subjected to an evaluation according to the steps of FIG. 3. For this purpose, cyclovoltagrams of urine samples have been recorded before, which have been taken from test subjects who have not been given vitamin C before. The recorded cyclovoltagrams of these urine samples have served as reference samples and have been used to form a mapping rule and a transformation matrix respectively for measuring vectors of cyclovoltagrams, as it is explained above referring to FIG. 3. By means of this transformation matrix which has been adjusted to urine measurements in this way, the measuring vectors and the reduced spectral measuring vectors respectively of the cyclovoltagrams 301 to 305 have been transformed into a two dimensional feature space.

FIG. 5 illustrates the two dimensional feature space in which the reduced spectral measuring vectors of FIG. 4 have been transformed. The feature space is especially spanned by two axes 400 and 410 which correspond to the two eigenvectors with the largest eigenvalues. The two axes 400 and 410 of FIG. 5 are standardized in such a way that the variance of feature values yields one (Unit Variance). In accordance with the main component analysis used, the axes 400 and 410 are called “main axis 1” and “main axis 2” respectively.

As can be seen in FIG. 5, five accumulations or clusters 301′, 302′, 303′, 304′ and 305′ of feature points can be recognized in the feature space. Each accumulation 301′, 302′, 303′, 304′ and 305′ is composed of four feature points which, by the main component transformation mentioned above, have been obtained from the cyclovoltagrams shown in FIG. 4, by rendering them noisy by a Gaussian distribution. The evaluation according to the feature processing, in this case being the main component analysis, consequently yields, in spite of a noisy rendering of the measuring vectors and the cyclovoltagrams 301 to 305 of FIG. 1 respectively with 10% relative noise of the maximum value, an unambiguous separation of the different urine samples, as it can be seen in FIG. 5 at the accumulations 301′ to 305′. As mentioned above, the axes are standardized in such a way that the variance of the feature values yields 1. In particular, the accumulation 301 of feature points corresponds to the cyclovoltagram 301 of FIG. 4, the accumulation 302′ of feature points to the cyclovoltagram 302 of FIG. 4, etc.

Due to the accumulations 301′ to 305′ being separated clearly, it is possible to associate further measurements of urine samples which are taken from persons without their knowledge, to certain classes. In the example of FIGS. 4 and 5, it is, for example, known that the sample liquid of the cyclovoltagram 301 of FIG. 4 was a urine sample which was taken from a patient prior to administering vitamin C. It is also known that the sample liquids of the cyclovoltagrams 302, 303 and 304 of FIG. 4 were urine samples, which were taken from a patient after administering vitamin C. Finally, it is also known that the sample liquid of the cyclovoltagram 305 of FIG. 4 was a urine sample that was taken from a patient prior to administering vitamin C and to which vitamin C was added afterwards. A new recording and processing of a cyclovoltagram of a urine sample of an unknown test subject can, for example, now be interpreted in that the test subject has either not been administered vitamin C before taking the urine sample, that the test person has been administered vitamin C or that the test subject has not been administered vitamin C before taking the sample, but that vitamin C has been added to the urine sample afterwards

Such a qualitative classification could be carried out the following way by at first determining the center of gravity of the accumulations 301′ of feature points. The determination of the center of gravity can, for example, be carried out by geometrical means. The centers of gravity of the accumulations 302′, 303′ and 304′ of the feature points are then determined. Finally, the center of gravity of the accumulation 305′ is determined. The distance between the feature point which is associated to the urine sample of the unknown test subject and each of the three centers of gravity is then determinred. Each distance can, for example, correspond to a Mahalanobis distance. If the distance to the center of gravity of 301′ is the smallest, it is deduced that the patient has not taken in vitamin C prior to taking the urine sample, If the feature point is closest to the center of gravity of 302′, 303′ and 304′, it is deduced that the test subject has taken in vitamin C prior to taking the urine sample. Finally, if the feature point is closest to the center of gravity of 305′, it is deduced that the test subject has not taken in vitamin C prior to taking the urine sample, but that vitamin C has been added to the urine sample later on.

After it has been illustrated in FIG. 5 how a qualitative association of cyclovoltagrams to classes is possible, it is explained referring to FIG. 6 how a quantitative value, which is associated to the sample liquid can be obtained from a cyclovoltagram of a sample liquid according to the inventive method.

In FIG. 6, the y-axis 500 shows the period of time in minutes, which indicates the time that has actually gone by between administering the vitamin C and taking the urine sample. The x-axis 505 shows the respective time values in minutes, wherein the time values have evolved from the feature points for seven noisy measuring vectors of four respective urine samples, as will now be explained.

As it has already been explained referring to FIGS. 4 and 5, the four measuring vectors which evolved from the urine samples taken at different points in time, after rendering noisy of the measuring data were transformed to seven feature points respectively, whereby four accumulations of these feature points evolved. The points in time at which the samples have been taken represent one feature of the urine samples. The accumulations of feature points are associated to the individual urine samples and, consequently, to the points in time of their taking. Then, an interpolation has been performed in a linear way via these associated pairs of accumulations and time values, wherefrom an association was achieved, which associates each point in the feature space to a time value. The 28 points, which can be seen in FIG. 6, which are separated into four accumulations 510, 520, 530 and 540, represent the time values associated to the respective feature points. It becomes evident that, in spite of rendering noisy the measuring dates, the period of time between administering vitamin C and taking the urine sample can be determined relatively precisely. In order to improve the precision, an interpolation of a higher rank can be used instead of a linear interpolation. Spline functions can also be used to interpolate between the different feature accumulations.

It has just been shown that the inventive apparatus and the inventive method, respectively, are capable of determining different characteristics of urine samples. It has especially been made clear that both qualitative and quantitative statements can be made about the urine samples.

However, it is noted that the present invention can also be used with other body liquids, such as liquor, blood, etc., or with liquid foods. Basically the present invention can also be used with other chemical solutions of all kinds, both organic and inorganic liquids, which are for one thing adequately conductive to be able to record a cyclovoltagram and which are homogenous for another thing. Consequently the present invention can especially be used with washing liquids for washing machines and dishwashers (washing liquor), for example. If the liquid to be measured is not adequately conductive, a respective conductivity can be obtained by adding an electrolyte.

It is also noted that, although the usage of only three electrodes has been described before, more electrodes can also be used so that, for example, measurements with different electrode materials can be recorded simultaneously.

The necessary calculations which have to be carried out with the transformations and mathematical operations respectively can either be carried out by a computer program which is carried out in a processor, an application specific IC (ASIC) or the like.

Although it has been described before referring to FIG. 3 that, for calculating the transformation matrix for transforming the measuring vectors into the feature space a plurality of measuring vectors are recorded and used, a plurality of measuring vectors can also be obtained and used by rendering noisy a recorded measuring vector by rendering it noisy with a Gauss-distributed noise.

It is also noted that, although it has been described before that the measuring vectors, before they are transformed into the feature space, are condensed by applying a mathematical operator and by cutting certain spectral values afterwards, it is also possible to apply the main component analysis directly to the measuring vectors.

It is noted that the method which has been described before is a “supervised” method in that there are supporting positions in the feature space, by means of which an interpolation is carried out in order to enable an association between feature points characteristics. However, the present method can also be implemented as an “unsupervised” method wherein there are no supporting positions but wherein a classification is deduced afterwards by means of certain correlations. Basically all multivariate signal processes can be used.

Thus, an advantage of the method described herein is that a feature vector does not have to be known a priori. After determining the eigensystems, the eigenvectors and the eigenvalues respectively, it can be determined a posteriori that the measuring vectors can obviously be associated to certain features in the system. These features or classes respectively can , for example, be illnesses. In another example they can also be concentrations of certain substances. In the last-mentioned case it is, by constructing a model, of course possible to map a new measuring vector on a certain concentration from a continuous range or, as it has been mentioned before, on the period of time between taking the sample and administering the drug.

It is also possible to use other methods instead of the main component analysis mentioned before in order to map the measuring vectors obtained in a low dimensional space. The methods of statistics and of the neuronal nets are suitable analyzing algorithms. With the help of these methods even those features can be extracted from the measuring graph, which are, even for a skilled analyzer, difficult to recognize or cannot be recognized at all. Basically these algorithms are mapping rules of a coordinate system of the measuring vectors into another low dimentional coordinate system of features or physical and chemical quantities respectively, wherein the coordinate system contains the evaluation. The main component analysis is one example of an advantageous method for this purpose, which is able to extract features which make a classification possible, from measuring graphs. A substantial advantage of the method is that it can also be used as an “unsupervised” method without knowing the results, wherein, nevertheless, differences and classes in the samples can be detected by , for example, determining certain correlations with certain characteristics a posteriori. Since this refers to a matrix mapping, the method is linear and stable.

The classes cannot only be associated to concentrations of individual substances, they can , for example, also identify certain states of illnesses which are correlated with certain metabolic products. The latter renders the method especially interesting for a quick analysis of illnesses In the transformed vector space of the main components interpolation methods for measuring concentrations can then also be used, as, for example, in FIG. 6, or the classification can be used as a basis for the method of the so-called partial model building.

The method discussed here for analyzing features, that is the main component analysis, is, however, substantially linear, which on the one hand renders it stable, but which in the case of high non-linearity limits its applicability. In the case of non-linear relations methods of the artificial neuronal nets can be used advantageously, either in the form of self organizing nets (SOM) for classification or “classical” neuronal nets for quantification. The methods of the neuronal nets are not linear and can thus deal with more cases of application than linear methods, but the disadvantage is that they are less stable than the main component analysis. Due to the larger degree of freedom they also require higher calibration requirements in order to achieve a stable mapping rule.

1. A method for determining characteristics of a sample liquid including a plurality of substances, wherein the method comprises the following steps:
recording (220) current-voltage measurement data of a liquid with at least one known characteristic;
transforming (235) the measurement data of the liquid into a feature space to obtain a first plurality of feature values;
recording (240) current-voltage measurement data of the sample liquid;
transforming (255) the measurement data of the sample liquid into the feature space to obtain a second plurality of feature values;
determining (260) at least one characteristic of the sample liquid based on the feature values of the sample liquid in relation to the feature values of the liquid with the at least one known characteristic;
wherein the steps of recording comprise the following steps:
cyclically applying a voltage ramp to the liquid in both directions; and
measuring the electrolysis current as a function of the voltage applied.

2. A method of claim 1, wherein the liquids are a body liquid, liquid foods or washing liquids.

3. A method of claim 1 or 2, wherein the at least one characteristic corresponds to a concentration of the plurality of substances, a statement of diagnosis of illness or the period of time between taking the sample and administering a drug.

4. A method of one of the claims 1 to 3, further comprising the following steps:
recording (200) current-voltage measurement data of a plurality of liquids which are predetermined as reference liquids;
determining (215) a transformation matrix for the steps of transforming (235, 255) into the feature space.

5. A method of claim 4, wherein the step of recording (200) the current-voltage measurement data of a plurality of reference liquids further comprises the following step:
rendering noisy the recorded current-voltage measurement data to obtain further current-voltage measurement data.

6. A method of claim 4 or 5, wherein the step of rendering noisy is carried out by adding a Gauss-distributed noise to the measurement data.

7. A method of one of the claims 4 to 6, wherein the step of determining (215) the transformation matrix comprises the following steps:
forming a covariance matrix from the measurements data of the plurality of reference liquids;
calculating the eigenvalues and the eigenvectors of the covariance matrix belonging thereto; and
forming the transformation matrix such that the transformation matrix provides a mapping rule for measuring vectors into a space which is spanned by the eigenvectors, of which the eigenvalues belonging thereto exceed an empirically predetermined threshold value.

8. A method of one of the claims 1 to 7, wherein the step of determining (260) of at least one characteristic of the sample liquid comprises the following steps:
determining the distance between the feature values of the sample liquid and the feature values of the liquid with the at least one known characteristic; and [symbol]
transformed to obtain a plurality nf feature vectors in the feature space.

10. A method of claim 9, wherein the step of determining (260) the at least one characteristic of the sample liquid comprises the following steps;
determining the distances between the feature values of the sample liquid and the feature vectors; and
associating the at least one known characteristic of the liquid with at least one known characteristic which is associated to the feature vector with the smallest distance, to the sample liquid.

11. A method of claim 9, wherein the at least one known characteristic of the plurality of liquids with at least one known characteristic are quantitative values which are related to one attribute, wherein the step of determining (260) the at least one characteristic of the sample liquid comprises the following steps:
interpolating between the feature values and the quantitative values of the plurality of liquids with at least one known characteristic to obtain an interpolation function which is defined in the feature space; and
associating the value of the interpolation function on the location of the feature values of the sample liquid to the sample liquids.

12. A method of one of the claims 1 to 11, further comprising the following step:
calculating (205, 225, 245) the Fourier transform function of the measurement data,
wherein the steps of transforming are applied to the Fourier transform function of the measurement data.

13. A method of one of the claims 1 to 11, further comprising the following step:
carrying out a wavelet transformation of the measurement data,
wherein the steps of transforming are applied to the measurement data which have been subjected to a wavelet transformation.

14. A method of claim 12 or 13, further comprising the following step:
picking out (210, 230, 250) transformed measurement data, the sum of which is larger than a certain percentage of the total sum of all transformed measurement data,
wherein the steps of transforming are applied to the transformed measurement data picked out.

15. A method of one of the previous claims, wherein an electrode material used for recording current-voltage measurement data is the same for each of the steps (200, 220, 240) of recording.

16. A method of one of the previous claims, wherein the steps (200, 220, 240) of recording are carried out several times, wherein an electrode material used for recording current-voltage measurement data is changed each time, and wherein the several current-voltage measurements data are combined.

17. A method of claim 16, wherein a scan speed used for recording current-voltage measurement data is the same for each of the steps (200, 220, 240) of recording.

18. A method of one of the previous claims, wherein the steps (200, 220, 240) of recording are carried out several times, wherein a scan speed used for recording current-voltage measurement data is changed each time, and wherein the several current-voltage measurement data are combined.

19. A method of one of the previous claims, further comprising the following step:
prior to the steps (200, 220, 240) of recording, diluting the liquids until the liquids exhibit a predetermined conductivity value.

20. A method of one of the previous claims, further comprising the following step:
prior to the steps (200, 220, 240) of recording, introducing (40) an inert gas into the liquid to drive out oxygen dissolved in the liquid.

21. An apparatus for determining characteristics of a sample liquid including a plurality of substances, the apparatus comprising the following features:
a recording means for recording current-voltage measurement data of a liquid with at least one known characteristic and for recording current-voltage measurement data of the sample liquid;
a first processing means for transforming the measurement data of the liquid into a feature space to obtain a first plurality of feature values, and for transforming the measurement data of the sample liquid into the feature space to obtain a second plurality of feature value; and
a second processing means for determining at least one characteristic of the sample liquid based on the feature values of the sample liquid in relation to the feature values of the liquid with the at least one known characteristic,
wherein the recording means comprises the following features:
a voltage generating means for cyclically applying a voltage ramp to the liquid in both directions; and
a measuring means for measuring the electrolysis current as a function of the voltage applied.

22. An apparatus of claim 21, wherein the liquids are body liquids, liquid foods or washing liquids.

23. An apparatus of claim 21 or 22, wherein the at least one characteristic corresponds to a concentration of the plurality of substances, a statement of diagnosis of illness or the period of time between taking the sample and administering a drug.

24. An apparatus of one of the claims 21 to 23, further comprising:
a means for determining a transformation matrix for usage with the transformation into the feature space from recorded current-voltage measurement data of a plurality of liquids predetermined as reference liquids.

25. An apparatus of one of the claims 21 to 24, further comprising:
a means for calculating the Fourier transform function of the measurement data,
wherein the means for transforming transforms the Fourier transform function of the measurement data.

26. An apparatus of one of the claims 21 to 25, further comprising:
a means for carrying out a wavelet transformation of the measurement data,
wherein the means for transforming transforms the measurement data having been subjected to a wavelet transformation.

27. An apparatus of claim 2 or 26, further comprising:
a means for picking out transformed measurement data, the sum of which exceeds a certain percentage of the total sum of all transformed measurement data,
wherein the means for transforming transforms the transformed measurement data picked out.

28. An apparatus of one of the claims 21 to 27, wherein the recording means comprises the following features:
a measurement chamber (20),
a counter electrode (5), a working electrode (10) and a reference electrode (15), which are located in the measurement chamber (20), wherein a fixed reference voltage is applied to the reference electrode (15);
a voltage generating means (25) for applying a voltage between the counter electrode (5) and the working electrode (10);
a voltage measuring means (25) for detecting the voltage between the working electrode (10) and the reference electrode (15); and
a current measuring means (25) for detecting the current flowing between the working electrode (10) and the counter electrode (5).

29. An apparatus of claim 28, further comprising:
a means (30) for introducing an inert gas into the measurement chamber (20).

30. An apparatus of claim 28 or 29, wherein the three electrodes (5, 10, 15) are fixed to a probe, wherein the probe is replaceable.

31. An apparatus of claim 30, wherein the probe comprises the following feature:
a means for amplifying the current flowing between the electrodes.

32. An apparatus of claim 30 or 31, wherein the probe further comprises the following feature:
a means for controlling the temperature at the electrodes (5, 10, 15).

33. An apparatus of one of the claims 30 to 32, wherein the probe comprises several sets of electrodes (5, 10, 15) with different materials.

34. An apparatus of claim 33, wherein the electrode material is gold, platinum or graphite.
